(19) United States
(12) Patent Application Publication
(10) Pub. No.: US 2024/0404995 A1
(43) Pub. Date: Dec. 5, 2024

(54) APPARATUS INCLUDING SELECTABLE CIRCUIT PLACEMENT MECHANISM AND METHODS OF MANUFACTURING THE SAME

(71) Applicant: Micron Technology, Inc., Boise, ID (US)

(72) Inventors: Chin Hui Chong, Singapore (SG); Hong Wan Ng, Singapore (SG); See Hiong Leow, Singapore (SG); Ling Pan, Singapore (SG); Seng Kim Ye, Singapore (SG); Kelvin Tan Aik Boo, Singapore (SG)

(21) Appl. No.: 18/646,688

(22) Filed: Apr. 25, 2024

Related U.S. Application Data
(60) Provisional application No. 63/471,218, filed on Jun. 5, 2023.

(51) Int. Cl. H01L 25/065; H01L 25/00; H05K 1/02; H10B 80/00

(52) U.S. Cl. CPC H01L 25/0657; H01L 25/50; H05K 1/0296; H10B 80/00; H01L 2225/06506; H01L 2225/0651; H01L 2225/06562

(57) ABSTRACT

An apparatus includes selectable a circuit placement mechanism configured to support two or more different circuit layouts. The circuit placement mechanism may include an overlap of electrical connections associated with the two or more circuit layouts and joined through an etch back selector. The etch back selector may enable the apparatus to function according to a selected one of the two or more different circuit layouts.

### CROSS-REFERENCE TO RELATED APPLICATION(S)

The present application claims priority to U.S. Provisional Patent Application No. 63/471,218, filed Jun. 5, 2023, the disclosure of which is incorporated herein by reference in its entirety.

### TECHNICAL FIELD

The present technology is directed to apparatuses, such as semiconductor devices including memory and processors, and several embodiments are directed to semiconductor devices that include selectable circuit placement mechanism.

### BACKGROUND

The current trend in semiconductor fabrication is to manufacture smaller and faster devices with a higher density of components for computers, cell phones, pagers, personal digital assistants, and many other products. Additionally, the device manufacturers are faced with persisting demand for lower prices. Accordingly, circuit designs and components that accommodate the higher density along with the lower costs are ideal.

### BRIEF DESCRIPTION OF THE DRAWINGS

FIG. 1 is a side view of a higher capacity semiconductor package.

FIG. 2A is a side view of a first lower capacity semiconductor package.

FIG. 2B is a side view of a second lower capacity semiconductor package.

FIG. 3A is a schematic view of an apparatus having a selectable circuit placement mechanism in accordance with embodiments of the technology.

FIG. 3B is a cross-sectional view of the apparatus of FIG. 3A in accordance with embodiments of the technology.

FIG. 3C is a cross-sectional view of the apparatus of FIG. 3B having to a first connection configuration in accordance with embodiments of the technology.

FIG. 3D is a cross-sectional view of the apparatus of FIG. 3B having to a second connection configuration in accordance with embodiments of the technology.

FIG. 4A is a cross-sectional view of a first semiconductor package according to the first connection configuration of the selectable circuit placement mechanism in accordance with embodiments of the technology.

FIG. 4B is a cross-sectional view of a second semiconductor package according to the second connection configuration of the selectable circuit placement mechanism in accordance with embodiments of the technology.

FIG. 5 is a flow diagram illustrating an example method of manufacturing an apparatus in accordance with an embodiment of the present technology.

FIG. 6 is a schematic view of a system that includes an apparatus configured in accordance with embodiments of the present technology.

### DETAILED DESCRIPTION

In the following description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with semiconductor devices are not shown, or are not described in detail, to avoid obscuring other aspects of the technology. In general, it should be understood that various other devices, systems, and methods in addition to those specific embodiments disclosed herein may be within the scope of the present technology.

Several embodiments of semiconductor devices, packages, and/or assemblies in accordance with the present technology can include a substrate (e.g., a printed circuit board (PCB)) having a selectable circuit placement mechanism. The selectable circuit placement mechanism can be configured to support two or more circuit placement configurations and corresponding connection locations.

As an illustrative example, the substrate with the selectable circuit placement mechanism can be used for manufacturing a first device/system having one memory devices at one location or a second device/system having memory devices located at two or more locations. The one location device can correspond to a simpler or cheaper electronic device having a microcontroller mounted on the substrate and one memory device or a stack of two or more memory devices mounted at a location that is separated from the microcontroller by a lateral distance. The same substrate can be used to manufacture a different device (e.g., a device having a greater number of memory devices) that includes one or more memory devices stacked with or over the microcontroller.

To support the different circuit location configurations and the corresponding connection requirements, the substrate can include the selectable circuit placement mechanism that can selectively support the one-location configuration or the multi-location configuration. The substrate can include electrical connections that generally support the different circuit placement configurations, and the selectable circuit placement mechanism can provide an adjustment that adapts the shared electrical connections specifically to a selected configuration.

In some embodiments, the selectable circuit placement mechanism can include an etch back section having a number of feature groupings that match the available configurations. For example, for the substrate supporting the one-location and multi-location (e.g., two location) configurations, the etch back section can include two groupings (e.g., two rows or columns) of etchable features. Etching back one grouping during manufacturing can adapt the substrate to one placement configuration (e.g., one-location configuration), and etching back a different grouping can adapt the substrate to another placement configuration (e.g., multi-location configuration). The etch back section can allow bond finger and routing on different locations.

Accordingly, the substrate having the selectable circuit placement mechanism can provide a common basis for supporting multiple different devices. In other words, the substrate can be fungible and support multiple designs. Thus, the substrate having the selectable circuit placement mechanism can reduce the costs associated with designing and manufacturing separate and dedicated substrates. Moreover, the increased usage of a common substrate can provide increased consumption of required materials and components, which can be leveraged for bulk purchases and other price reductions for the required materials and components. The selectable circuit placement mechanism can leverage an existing manufacturing process, such as the etch back process, to minimize the impact of any additional (e.g., selection) steps. Moreover, the common basis for the design can allow reduced time to market, such as by enabling a single substrate to cater to industry demand for multiple configurations, reduced design cycle time, and so forth. Details regarding the selectable circuit placement mechanism are described below.

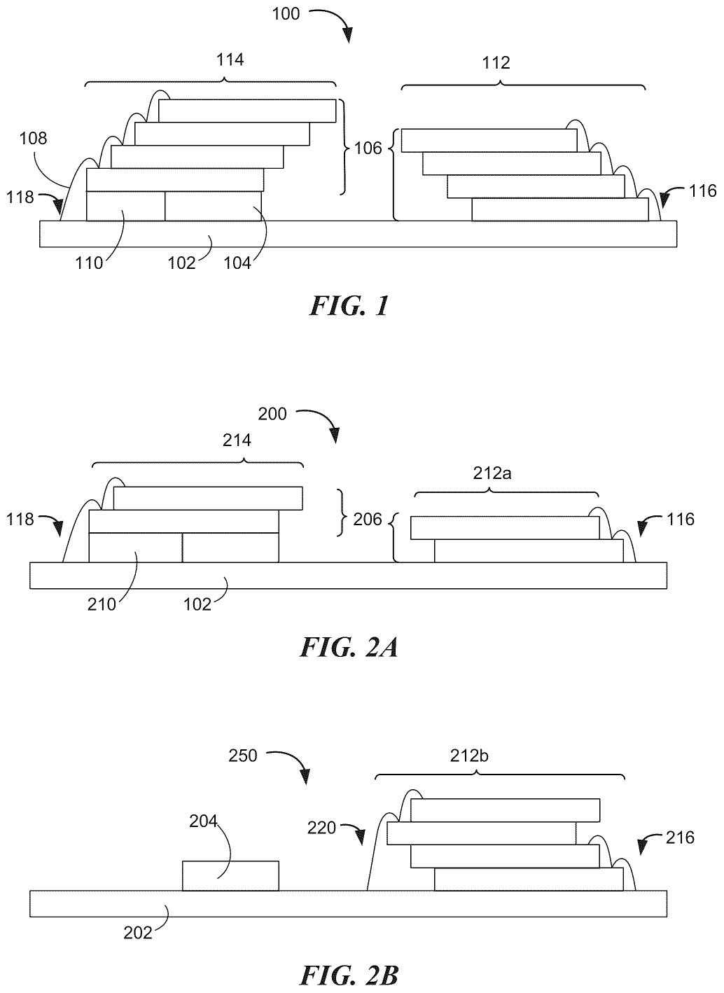

For comparison purposes, FIG. 1 illustrates a side view of a conventional higher capacity semiconductor package 100 (package 100). The package 100 can include a substrate 102 having mounted thereon a microcontroller 104 (e.g., a central processing unit (CPU)) and a set of memory devices 106 (e.g., volatile and/or non-volatile memories). The memory devices 106 and/or the microcontroller 104 can be electrically coupled to the substrate 102 using connectors 108 (e.g., bond wires), traces, connection planes, vias, and/or other conductive structures.

To accommodate a higher device capacity (e.g., a higher quantity of memory devices), the devices may be stacked on top of each other. For example, the package 100 can include a first stack 112 having a set (e.g., half the total quantity) of memory devices and a second stack 114 having a remainder of the memory devices stacked with the microcontroller 104, a silicon spacer 110, or a combination thereof. To support the multiple stacks, the substrate 102 can include stack-specific connection locations. In some embodiments, the stack-specific connection locations can be located on a peripheral portion of the substrate 102, such as for a first peripheral connection location 116 for the first stack 112 and a second peripheral connection location 118 for the second stack 114.

The substrate 102 with its connection locations 116 and 118 may be reused for a different devices having lower device capacities (e.g., a lesser quantity of memory devices). FIG. 2 is a side view of a first lower capacity semiconductor package 200 (the “first package 200”) with a lower number of memory devices 206 (e.g., four memory dies instead of eight memory dies of FIG. 1). The first package 200 can include the same substrate 102 as the package 100 of FIG. 1 and have the same number of stacks (e.g., a stack 212a with memory devices and a stack 214 having memory devices with a microprocessor and/or a spacer 210) located at the same locations as the package 100. Accordingly, the same connection locations 116 and 118 can facilitate corresponding stacks 212 and 214.

However, for some applications or design goals, it may be beneficial to have different placement locations for one or more of the devices. FIG. 2B is a side view of a second lower capacity semiconductor package 250 (the “second package 250). The second package 250 can have the same device capacity as the first package 200 but with a different placement configuration. For example, the second package 250 can include the same number of memory devices as the first package 200 but located differently, such as forming a single stack 212b. A microprocessor 204 may be mounted on the substrate 202 and remain uncovered or exposed (e.g., without any memory or other devices stacked on top thereof).

In comparison to the first package 200 of FIG. 2A, the second package 250 of FIG. 2B can provide a less complex stack design, eliminate the silicon spacer 210 of FIG. 2A, and/or expose the microprocessor 204. For example, the thermal management of the microprocessor 204 may be improved for the second package 250 over the first package 200 while retaining the same device capacity.

However, the connection configuration for the second package 250 is different than the first package 200. As illustrated in FIG. 2B, the single stack 212b includes devices (e.g., top half of memory devices) that connect to a different circuit than others in the stack, thereby deviating from the connection configuration of the first package 200. For example, the second package 250 includes a substrate 202 having a middle connection location 220 located between the single stack 212b and the microprocessor 204. Accordingly, the substrate 102 of FIG. 2A and the substrate 202 have different electrical connections that are specific to the corresponding packages 200 and 250, respectively.

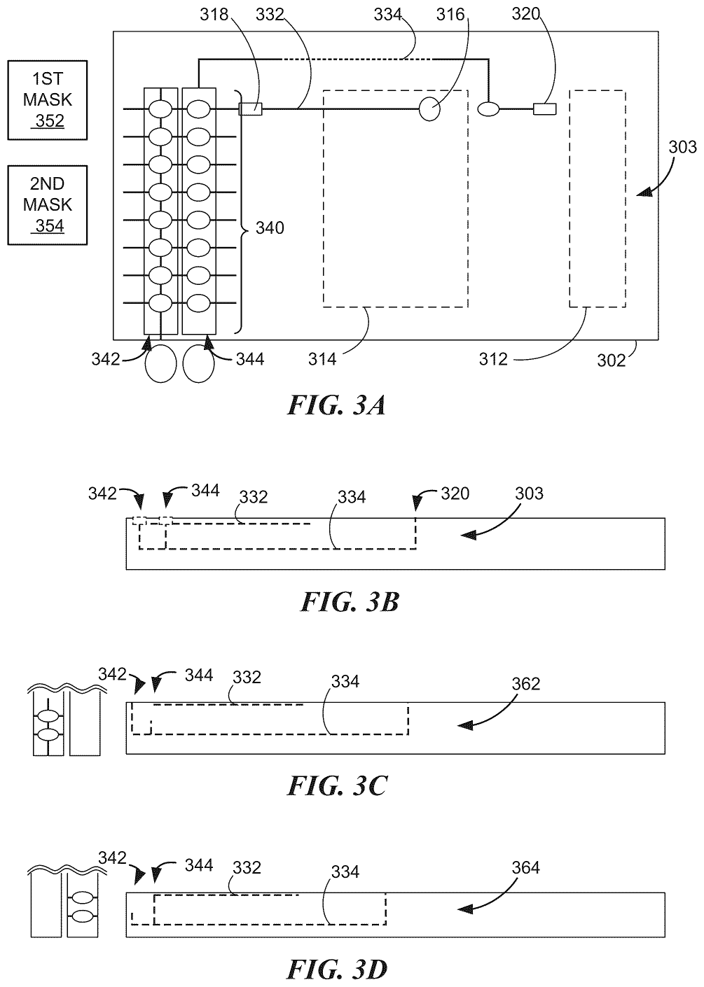

In contrast to such conventional approaches that use substrates having one placement location, FIG. 3A is a schematic view of an apparatus (e.g., a multi-configuration substrate 302) having a selectable circuit placement mechanism 303 in accordance with embodiments of the technology. The multi-configuration substrate 302 can include the selectable circuit placement mechanism 303 configured to selectively support connections for a one-stack configuration and a multi-stack configuration. In other words, the selectable circuit placement mechanism 303 can support electrical connections from devices located at a first stack location 312, a second stack location 314, or a combination thereof.

In some embodiments, the selectable circuit placement mechanism 303 can include (1) a controller connection location 316 for electrically coupling to a controller, (2) a stack-side connection location 318, and (3) a cross-stack connection location 320 for supporting the multiple selectable circuit placement configurations. Illustrating an embodiment of the selectable circuit placement mechanism 303, FIG. 3B is a cross-sectional view of the apparatus of FIG. 3A in accordance with embodiments of the technology.

The connection locations 316, 318, and 320 can include electrical connection/contact pads. The selectable circuit placement mechanism 303 can include a stack-side routing connection 332 and a cross-stack routing connection 334 that connect the stack-side connection location 318 and the cross-stack connection location 320 to the controller connection location 316. For example, the stack-side routing connection 332 can include a trace extending along a lateral direction from the second stack location 314 to a peripheral portion of the multi-configuration substrate 302. Accordingly, the stack-side routing connection 332 can provide a direct electrical connection between the controller connection location 316 and the stack-side connection location 318. Also, the cross-stack routing connection 334 can be connected to the stack-side routing connection 332 (through, e.g., one or more vias) and extend from the peripheral portion (e.g., from under the stack-side connection location 318) to the cross-stack connection location 320. Accordingly, the cross-stack routing connection 334 can provide an electrical path between the controller connection location 316 to the cross-stack connection location 320. In some embodiments, the cross-stack routing connection 334 can be formed on a layer below the stack-side routing connection 332.

The selectable circuit placement mechanism 303 can include a selector 340 disposed between and electrically connecting the cross-stack routing connection 334 to the stack-side routing connection 332. In some embodiments, the selector 340 can include a first selection section 342 and a second selection section 344 configured to be etched back during manufacturing. For example, a first selection mask 352 can be used to cover the first selection section 342 and etch away or remove the second selection section 344. Alternatively, a second selection mask 354 can be used to cover the second selection section 344 and etch away or remove the first selection section 342. Retaining the selected section and etching away the non-selected section can break certain connections between the cross-stack routing connection 334 to the stack-side routing connection 332, thereby adapting the connections according to the targeted device configuration.

Illustrating a first selection, FIG. 3C is a cross-sectional view of the apparatus (e.g., the multi-configuration substrate 302) of FIG. 3B having to a first connection configuration 362 in accordance with embodiments of the technology. The first connection configuration 362 can be the result of retaining the first selection section 342 and etching back or removing the second selection section 344. Accordingly, the stack-side routing connection 332 can be electrically isolated from the cross-stack routing connection 334. In some embodiments, the first selection section 342 can be coupled to an electrical ground or to power, thereby grounding or powering the cross-stack routing connection 334.

For the first connection configuration 362, the stack-side routing connection 332 can be used to connect the stack-side connection location 318 of FIG. 3A to the controller connection location 316 of FIG. 3A. Accordingly, the first connection configuration 362 can provide connections between the controller at the second stack location 314 of FIG. 3A and the memory devices stacked thereon. The cross-stack connection location 320 of FIG. 3A can remain unused.

Illustrating a second selection FIG. 3D is a cross-sectional view of the apparatus of FIG. 3B having to a second connection configuration 364 in accordance with embodiments of the technology. The second connection configuration 364 can be the result of etching back the first selection section 342 and retaining the second selection section 344. Accordingly, the stack-side routing connection 332 can be electrically connected or remain connected to the cross-stack routing connection 334. In some embodiments, when the first selection section 342 is coupled to an electrical ground or a power source, etching back the first selection section 342 can isolate the stack-side routing connection 332 and the cross-stack routing connection 334 from the electrical ground/power.

For the second connection configuration 364, the stack-side routing connection 332 and the cross-stack routing connection 334 can be used to connect the cross-stack connection location 320 of FIG. 3A to the controller connection location 316 of FIG. 3A. Accordingly, the second connection configuration 364 can support or provide connections between the controller at the second stack location 314 of FIG. 3A and memory dies at the first stack location 312 of FIG. 3A. The stack-side connection location 318 of FIG. 3A can remain unused.

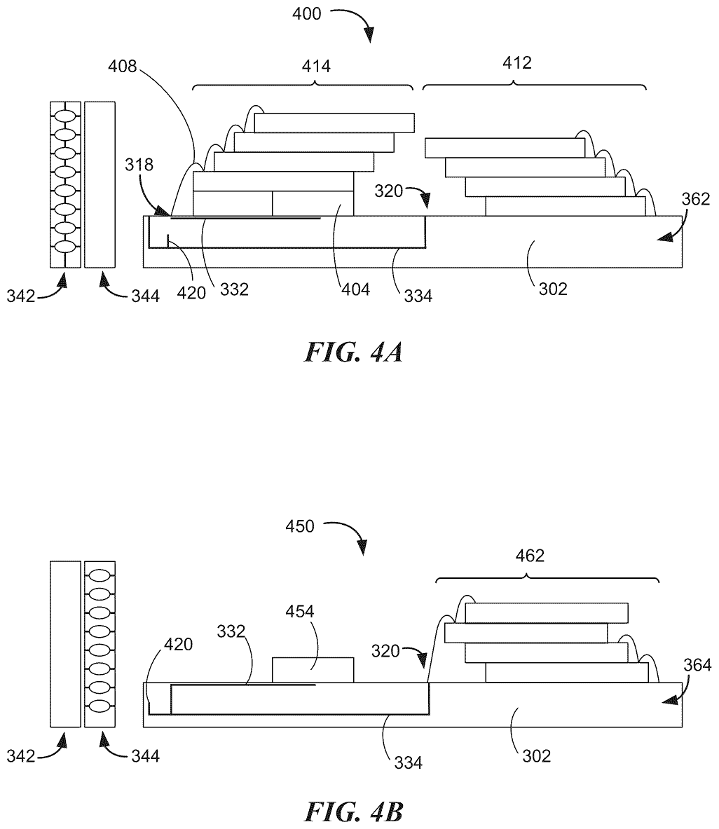

FIGS. 4A and 4B illustrate the difference device configurations (e.g., device locations and corresponding connections) that correspond to the first and second connection configurations 362 and 364, respectively. FIG. 4A is a cross-sectional view of a first semiconductor package 400 according to the first connection configuration 362 (e.g., one channel fanout configuration) of the selectable circuit placement mechanism 303 in accordance with embodiments of the technology. FIG. 4B is a cross-sectional view of a second semiconductor package 450 according to the second connection configuration 364 (e.g., a two channel fanout configuration) of the selectable circuit placement mechanism 303 in accordance with embodiments of the technology.

Referring now to FIG. 4A, the first semiconductor package 400 can include a first stack 412 of semiconductor devices and a second stack 414 of semiconductor devices mounted on the multi-configuration substrate 302. The first stack 412 can include a set of memory devices (e.g., 1, 2, 4, or a different number of devices), and the second stack 414 can include a separate set of memory devices (e.g., 1, 2, 4, or a matching number of devices as those in the first stack 412) stacked on top of a microcontroller 404. In some embodiments, a silicon spacer can be disposed under the memory devices in the second stack 414.

The devices in the first stack 412 can be connected to one or more connection locations on a portion of the multi-configuration substrate 302 opposite or away from the microcontroller 404. The stacked devices in the second stack 414 can be connected, such as using device connectors 408 (e.g., bond wires), at the stack-side connection location 318. Based on the removal of the second selection section 344 for the first connection configuration 362, the stack-side routing connection 318 can electrically couple the device connectors 408 and the stacked memory devices to the microcontroller 404. The remaining first selection section 342 can connect the cross-stack routing connection 334, the cross-stack connection location 320, or both to ground/power, thereby providing noise reduction and shielding for the microcontroller 404 and/or the second stack 414. The cross-stack connection location 320 can remain unconnected/unused.

When etch back selectors 340 are used, the resulting packages can include an etch back artifact 420 that remains from the initially existing portion of the shared connection. The etch back artifact 420 can include a vertically extending conductive structure (e.g., a partial via) that previously connected to the etched back/removed portion of the selector 340. Accordingly, the etch back artifact 420 can be located under a surface location absent of an electrical connector (e.g., location previously occupied by the etched back selection section) and remain buried within the substrate with its terminal end unconnected to a circuit component (e.g., without an electrical purpose for the vertical extension). Also, the etch back artifact 420 can be adjacent to (e.g., within a threshold distance from) and/or electrically coupled to the remaining selection section. For the example package 400, the etch back artifact 420 can be located between the first selection section 342 and the stack-side connection location.

As a further result of using the etch back selectors 340, the resulting packages can include the remaining selection section (e.g., the first selection section 342 for the package 400). The remaining selection section can be available for an etch back process, such as by having electrical connections viewable or accessible on a top/mounting surface of the substrate. The exposed connections can have one or more remaining portions (e.g., lateral connections or extensions, nodes, connection pads, or the like) that that initially coupled to the etched back. As a result of the etch back selection, the remaining portions can be unterminated without connecting to any circuit components (e.g., without an electrical purpose for the lateral extensions, nodes, etc.).

Referring now to FIG. 4B, the second semiconductor package 450 can include a microcontroller 454 and a single stack 462 of devices (e.g., 1, 2, 4, or a different number of memory devices) mounted on the multi-configuration substrate 302 and separated along a lateral direction. For example, the microcontroller 454 and the stack 462 can be located across or on opposite sides of the cross-stack connection location 320. The microcontroller 454 can remain exposed and without other devices stacked on top thereof.

A portion (e.g., a top half) of the devices in the stack 462 can be electrically connected to the cross-stack connection location 320, and a remainder of the devices can be connected to a portion of the multi-configuration substrate 302 opposite or away from the microcontroller 404. Based on the removal of the first selection section 342 for the second connection configuration 364, the cross-stack connection location 320 can be electrically connected to the microcontroller 454 through the stack-side routing connection 332 and the cross-stack routing connection 334. Also, based on the removal of the first selection section 342, the stack-side routing connection 332 and the cross-stack routing connection 334 can be electrically separated from the ground/power connection at the first selection section 342 (e.g., on a higher/surface layer).

As a remnant of the etch back selection process, the example package 450 can include the etch back artifact 420 located beyond (e.g., farther away from the microcontroller 454) the second selection section 344. Also as a remnant of the etch back selection process, the package 450 can include the second selection section 344 with unconnected/unterminated portions exposed on the surface of the substrate. Moreover, the stack-side connection location 318 of FIG. 3A can remain unconnected/unused.

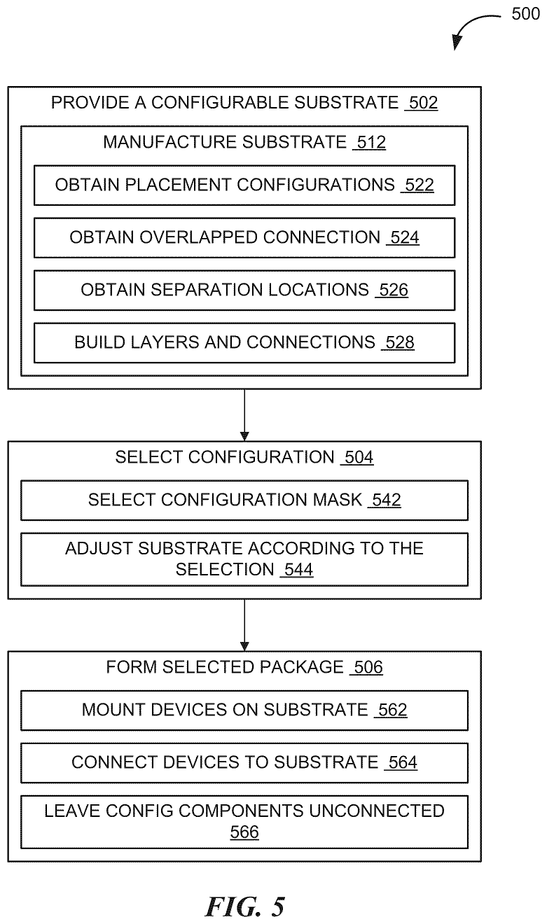

FIG. 5 is a flow diagram illustrating an example method 500 of manufacturing an apparatus (e.g., the multi-configuration substrate 302 of FIG. 3A, the first semiconductor package 400 of FIG. 4A, and/or the second semiconductor package 450 of FIG. 4B) in accordance with an embodiment of the present technology. The method 500 can be for manufacturing and/or utilizing the selectable/fungible substrate for supporting multiple package designs and/or the corresponding packages as described above.

The method 500 can include, such as illustrated at block 502, providing a configurable substrate, such as the multi-configuration substrate 302 of FIG. 3A. The provided configurable substrate can include connections (e.g., vias, traces, connectors, wires, and/or other electrical conductive structures) that can be adjusted to facilitate one or multiple circuit/package designs. For example, the configurable substrate can include the selectable circuit placement mechanism 303 of FIG. 3A having the shared electrical connection that can be adjusted (via, e.g., the selector 340 of FIG. 3A) to support one of the first connection configuration 362 of FIG. 3C, the second connection configuration 364 of FIG. 3D, and/or other configurations.

The configurable substrate can include a shared connection that initially includes an overlap of electrical connections for the supported circuit placement configurations/packages. As an illustrative example, the shared connection (e.g., the selectable circuit placement mechanism 303) can include (1) a first connection location and a first routing connection (e.g., the stack-side connection location 318 of FIG. 3A and the stack-side routing connection 332 of FIG. 3A) for the first connection configuration 362 and (2) a second connection location and a second routing connection (e.g., the cross-stack connection location 320 of FIG. 3A and the cross-stack routing connection 334 of FIG. 3A) for the second connection configuration 364. The second connection location may be between the microcontroller and a designated location for the single stack, and the first connection location may be opposite the second connection location across the microcontroller.

The configurable substrate can further include the selector 340 (e.g., the etch back selector) that can be used to adjust the shared connection for the selected one of the available configurations. For example, the selector 340 can include the first selection section 342 of FIG. 3A and the second selection section 344 of FIG. 3A that can be used to selectively and electrically disconnect the first and second routing connections. The first and second selection sections 342 and 344 can be coupled to each other and the shared connection (e.g., between the stack-side connection location 318 and the cross-stack connection location 320). The first selection section can further be electrically connected to an electrical ground or a power source.

In some embodiments, the method 500 can include, such as illustrated at block 512, manufacturing the configurable substrate. At blocks 522-526, the manufacturer can obtain the placement configurations, the overlapped/shared connections, and/or the separation locations. For example, a circuit/package designer can provide one or more of the details for manufacturing the configurable substrate. Also, the designer and/or the manufacturer can identify the package requirements and derive the placement configurations, the overlapped/shared connections, and/or the separation locations. At block 528, the substrate can be manufactured by building the layers and the connections (e.g., vias and traces).

The method 500 can include, such as illustrated at block 504, selecting one of the multiple available circuit placement or package configurations. The selection can correspond to the decision/identification that a particular configurable substrate is to be used to manufacture the corresponding package. For example, a package manufacturer can select the configurable substrate to manufacture one of the first package 400 and the second package 450. Accordingly, the package manufacturer can select the corresponding circuit placement configuration (e.g., the first connection configuration 362 for stacking memory devices over/under the microcontroller and the second connection configuration 364 for stacking the memory devices in one stack, respectively) and the signal routing paths unique to and/or utilized in the selected package.

In some embodiments, the selection can be made using an etch back process. For example, the method can include, as illustrated at block 542, selecting a configuration mask (e.g., the first selection mask 352 of FIG. 3A or the second selection mask 354 of FIG. 3A). According to the selected mask, the method can include adjusting the configurable substrate. At block 544, the configurable substrate can be adjusted according to the selected configuration, such as using the selected configuration mask. For example, the selected mask can be used to cover a portion of the selector 340 according to the selected circuit configuration, and the uncovered portion of the selector 340 can be etched back and removed from the configurable substrate. The etch back can selectively adjust the shared connection, such as by separating the stack-side routing connection 332, the cross-stack routing connection 334, ground/power source, or a combination thereof from a remainder of the shared connection. The etch back can leave the covered portion of the selector 340 remaining and facilitating the electrical connections for the selected circuit placement configuration.

The method 500 can include, such as illustrated at block 506, forming the selected package by mounting and connecting circuit components according to the selected configuration/package design. At block 562, the devices (e.g., semiconductor devices, active/passive components, or the like) may be mounted on the configured/adjusted substrate. For example, the microcontroller 404 of FIG. 4A/454 of FIG. 4B can be mounted at the second stack location 314 of FIG. 3A on the adjusted substrate. Also, the memory devices can be mounted at the first stack location 312 of FIG. 3A and/or over/under the microcontroller 404 at the second stack location 314.

At block 564, the mounted devices can be electrically coupled to the substrate and/or other components according to the selected configuration. For example, bond wires may be used to connect memory devices stacked with the microcontroller 404 to the stack-side connection location 318 for the first connection configuration 362. The configuration having multiple locations for the memory device can have the memory devices connected according to a single channel fanout configuration. Also, bond wires may be used to connect memory devices at the first stack location 312 to the cross-stack connection location 320 for the second connection configuration 364. The configuration having a single locations for the memory device can have the memory devices connected according to a two channel fanout configuration. The utilized connection locations can be connected to the stack-side routing connection 332, which can be electrically connected to the microcontroller.

In forming the selected package, the connection components may be left unconnected/unused as illustrated at block 566. For example, unselected connection locations (e.g., the cross-stack connection location 320 for the first connection configuration 362 or the stack-side connection location 318 for the second connection configuration 364) can remain unconnected to circuit components. Also, one of the selector portions with larger etchable regions can remain exposed on the top surface of the substrate without any bond wires connected thereto. Further etch back artifacts 420 of FIG. 4A/4B can remain within the substrate.

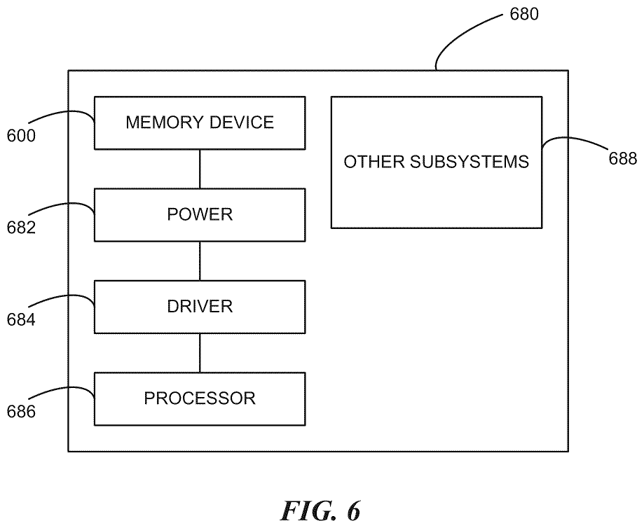

FIG. 6 is a schematic view of a system that includes an apparatus in accordance with embodiments of the present technology. Any one of the semiconductor devices described above with reference to FIGS. 3A-5 can be incorporated into any of a myriad of larger and/or more complex systems, a representative example of which is system 690 shown schematically in FIG. 6. The system 690 can include a semiconductor device 600 (“device 600”) (e.g., a semiconductor device, package, and/or assembly), a power source 692, a driver 694, a processor 696, and/or other subsystems or components 698. The device 600 can include features generally similar to those devices described above. The resulting system 690 can perform any of a wide variety of functions, such as memory storage, data processing, and/or other suitable functions. Accordingly, representative systems 690 can include, without limitation, hand-held devices (e.g., mobile phones, tablets, digital readers, and digital audio players), computers, and appliances. Components of the system 690 may be housed in a single unit or distributed over multiple, interconnected units (e.g., through a communications network). The components of the system 690 can also include remote devices and any of a wide variety of computer-readable media.

This disclosure is not intended to be exhaustive or to limit the present technology to the precise forms disclosed herein. Although specific embodiments are disclosed herein for illustrative purposes, various equivalent modifications are possible without deviating from the present technology, as those of ordinary skill in the relevant art will recognize. In some cases, well-known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein, and the invention is not limited except as by the appended claims.

Throughout this disclosure, the singular terms “a,” “an,” and “the” include plural referents unless the context clearly indicates otherwise. Similarly, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the terms “comprising,” “including,” and “having” are used throughout to mean including at least the recited feature(s) such that any greater number of the same feature and/or additional types of other features are not precluded. Reference herein to “one embodiment,” “an embodiment,” “some embodiments” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

What is claimed is:

1. A method of manufacturing an apparatus, the method comprising:
providing a multi-configuration substrate including a selectable circuit placement mechanism having a shared connection configured to provide electrical connections for two or more circuit placement configurations, the selectable circuit placement mechanism including an etch back selector configured to select from the two or more circuit placement configurations;
selecting one of the two or more circuit placement configurations based on etching back a portion of the etch back selector;
mounting a microcontroller on the multi-configuration substrate, wherein the mounted microcontroller is electrically coupled to the shared connection;
mounting at least one memory device on the multi-configuration substrate; and
electrically coupling the at least one memory device to the shared connection and the microcontroller.

2. The method of claim 1, wherein selecting the one of the two or more circuit placement configurations includes selecting between (1) a first circuit placement configuration for mounting at least a first memory device of the at least one memory device at a first location separated by a distance from the microcontroller and at least a second memory device of the at least one memory device stacked over or under the microcontroller or (2) a second circuit placement configuration for mounting the at least one memory device at the first location and maintaining the microcontroller unstacked.

3. The method of claim 2, wherein:
the shared connection includes (1) a first connection location and a first routing connection between the first connection location and the microcontroller for the first circuit placement configuration and (2) a second connection location and a second routing connection coupling the first routing connection to the second connection location for the second circuit placement configuration; and
the etch back selector is configured to selectively electrically disconnect the first and second routing connections.

4. The method of claim 3, wherein:
the etch back selector includes a first selection section electrically coupled to a second selection section and the shared connection; and
selecting the one of the two or more circuit placement configurations includes (1) covering one of the first or second selection section with a selection mask and (2) etching away an uncovered one of the first or second selection section.

5. The method of claim 3, wherein selecting the one of the two or more circuit placement configurations includes selecting the first circuit placement configuration by etching back a selection portion of the etch back selector that electrically connected the first and second routing connections to adjust the shared connection and disconnect the first routing connection from the second routing connections.

6. The method of claim 5, wherein:
the etch back selector includes a remaining selector portion electrically connected to the second routing connection and an electrical ground or a power source; and
selecting the first circuit placement configuration includes maintaining a connection between the second routing connection and the electrical ground or a power source.

7. The method of claim 6, wherein:
the second connection location remains unconnected for the first circuit placement configuration;
mounting the at least one memory device on the multi-configuration substrate includes (1) mounting the at least the first memory device at the first location, and (2) mounting the at least the second memory device over or under the microcontroller; and
further comprising:
connecting one or more bond wires between the at least the second memory device and the first connection location, wherein:
the first connection location is located (1) opposite the first location across the microcontroller and (2) between the remaining selector portion and the microcontroller; and
the at least the second memory device are electrically coupled to the microcontroller through the first routing connection.

8. The method of claim 7, wherein the first circuit placement configuration corresponds to a single channel fanout configuration for each of the at least the first memory device and the at least the second memory device mounted over different locations on the multi-configuration substrate to the microcontroller.

9. The method of claim 3, wherein:
the etch back selector initially includes (1) a first selector portion electrically connected to the second routing connection and an electrical ground and a (2) second selector portion connecting the first and second routing connections; and
selecting the one of the two or more circuit placement configurations includes selecting the second circuit placement configuration by etching back the first selection portion of the etch back selector to disconnect the electrical ground from the first and the second routing connections.

10. The method of claim 9, wherein:
the first connection location remains unconnected for the second circuit placement configuration;
the at least one memory device is electrically connected to the second connection location using one or more bond wires; and
at least a portion of the at least one memory device is connected to the microcontroller through the bond wires, the second connection location, the first routing connection, the remaining second selector portion, and the second the routing connection.

11. The method of claim 10, wherein:
the at least one memory device includes two or more stacked memory devices; and
the second circuit placement configuration corresponds to a two channel fanout configuration the two or more stacked memory devices.

12. The method of claim 3, wherein the second routing connection extends laterally along a layer under the first routing connection.

13. The method of claim 3, wherein:
the at least one memory device includes two or more memory devices; and
selecting the one of the two or more circuit placement configurations includes selecting between (1) mounting the two or more memory devices at two separate locations for a first circuit placement configuration or (2) mounting the two or more memory devices as a single stack at one location for a second circuit placement configuration.

14. The method of claim 13, wherein:
the multi-configuration substrate includes a first connection location and a second connection location configured to provide electrical coupling to the two or more memory locations for the first and second placement configurations, respectively; and
selecting the one of the two or more circuit placement configurations includes selecting a signal routing path between one of the first and second connection locations to the microcontroller.

15. The method of claim 14, wherein:
the shared connection initially includes and overlap of electrical connections between the microcontroller and the two or more memory devices for both the first and second placement configurations;
the second connection location is between the microcontroller and a designated location for the single stack; and
the first connection location is opposite the second connection location across the microcontroller.

16. A semiconductor package, comprising:
a microcontroller;
at least one memory device; and
a substrate having the microcontroller and the at least one memory device mounted thereon, wherein the substrate includes:
a substrate top surface;
one or more unused contact surfaces exposed on the substrate top surface and unconnected to the microcontroller and the at least one memory device;
active contact surfaces exposed on the substrate top surface and electrically connected to the microcontroller and the at least one memory device;
internal electrical connections on or within the substrate and electrically coupling the active contact surfaces, the one or more unused contact surfaces, or a combination thereof;
an etch back artifact including a conductive structure extending vertically above from the internal electrical connections toward the substrate top surface and buried under the top surface with a top portion of the etch back artifact unconnected; and
a remaining selector portion exposed on the substrate top surface, wherein the remaining selector portion is connected to the internal electrical connections using a via.

17. The semiconductor package of claim 16, wherein:
the at least one memory device includes (1) at least a first memory device mounted over the microprocessor at a first location and (2) at least a second memory device mounted at a second location; and
the internal electrical connections include (1) a first routing connection electrically coupling the at least first memory device to the microcontroller, and (2) a second routing connection electrically extending across the microcontroller and connected to the remaining selector portion and the one or more unused contact surfaces.

18. The semiconductor package of claim 17, wherein the remaining selector portion is connected to a power source or an electrical ground.

19. The semiconductor package of claim 16, wherein:
the at least one memory device includes two or more memory devices stacked at a location separate from the microcontroller;
the active contact surfaces are located between the microcontroller and the two or more stacked memory devices; and
the internal electrical connections include (1) a first routing connection electrically connected to the remaining selector portion and the one or more unused contact surfaces and (2) a second routing connection electrically connected to the remaining selector portion and the active contact surfaces.

20. A printed circuit board, comprising:
a processor mounting portion configured to receive and provide electrical connections to a microcontroller;
a memory mounting portion separated from the processor mounting portion and configured to receive at least one memory device;
a first set of contact surfaces configured to support a first circuit placement configuration representative of having additional memory devices stacked over or under the microcontroller;
a second set of contact surfaces configured to support a second circuit placement configuration representative of having the microcontroller unstacked and two or more stacked memory devices at the memory mounting portion;
a first routing connection electrically connecting the first set of contact surfaces to the electrical connections configured to connect to the microcontroller;
a second routing connection electrically connected the second set of contact surface and extending toward the first routing connection; and
an etch back selector on a top surface of the printed circuit board, the etch back selector disposed between and electrically connecting the first and second routing connections, wherein the etch back selector is configured to selectively break a connection between the first and second routing connections using an etch back process to select between the first and second circuit placement configurations.
